(19) United States
(12) Patent Application Publication
(10) Pub. No.: US 2025/0023529 A1
(43) Pub. Date: Jan. 16, 2025

(54) EQUALIZATION CIRCUIT AND RECEIVING CIRCUIT INCLUDING THE EQUALIZATION CIRCUIT

(71) Applicant: SK hynix Inc., Icheon-si Gyeonggi-do (KR)

(72) Inventor: Dae Joon KIM, Icheon-si Gyeonggi-do (KR)

(73) Assignee: SK hynix Inc., Icheon-si Gyeonggi-do (KR)

(21) Appl. No.: 18/531,417

(22) Filed: Dec. 6, 2023

(30) Foreign Application Priority Data
Jul. 13, 2023 (KR) 10-2023-0091160

(51) Int. Cl. H03F 3/45; H04L 25/02; H04L 25/03

(52) U.S. Cl. CPC H03F 3/45071; H04L 25/0272; H04L 25/03885

(57) ABSTRACT

An equalization circuit includes a first equalization circuit and a second equalization circuit. The first equalization circuit, when a swing width decrease signal is activated, adjusts a voltage level of a first signal line in accordance with a second equalization control signal and adjusts a voltage level of a second signal line in accordance with a first equalization control signal to decrease a swing width of a differential amplification signal transmitted over the first signal line and the second signal line. The second equalization circuit, when a swing width increase signal is activated, adjusts the voltage level of the second signal line in accordance with the second equalization control signal and adjusts the voltage level of the first signal line in accordance with the first equalization control signal to increase a swing width of the differential amplification signal.

### CROSS-REFERENCES TO RELATED APPLICATION

The present application claims priority under 35 U.S.C. § 119(a) to Korean application number 10-2023-0091160 filed on Jul. 13, 2023, in the Korean Intellectual Property Office, which is incorporated herein by reference in its entirety as set forth in full.

### BACKGROUND

### 1.Technical Field

Various embodiments generally relate to a semiconductor circuit, and more particularly to an equalization circuit and a receiving circuit including the equalization circuit.

### 2. Related Art

In the process of signal transmission in semiconductor apparatus, the swing width of the signal changes depending on the environment of the channel, and the signal transmission efficiency may decrease accordingly. Therefore, a receiving circuit having an equalization function can be used to eliminate the decrease in signal transmission efficiency. However, the equalization function alone cannot adjust the swing width of the signal as much as desired, which limits the improvement of signal transmission efficiency.

### SUMMARY

In an embodiment, an equalization circuit may include a first equalization circuit and a second equalization circuit. The first equalization circuit may be configured, when a swing width decrease signal is activated, to adjust a voltage level of a first signal line in accordance with a second equalization control signal and to adjust a voltage level of a second signal line in accordance with a first equalization control signal to decrease a swing width of a differential amplification signal transmitted over the first signal line and the second signal line. The second equalization circuit may be configured to, when a swing width increase signal is activated, to adjust the voltage level of the second signal line in accordance with the second equalization control signal and to adjust the voltage level of the first signal line in accordance with the first equalization control signal to increase a swing width of the differential amplification signal.

In an embodiment, a receiving circuit of a semiconductor apparatus may include a first amplification circuit, an equalization circuit and a control circuit. The first amplification circuit may be configured to amplify an input signal according to a reference voltage to generate a differential amplification signal, and to transmit the differential amplification signal to a first signal line and a second signal line. The equalization circuit may be coupled to the first signal line and the second signal line, and configured to decrease a swing width of the differential amplification signal in response to a swing width decrease signal, and to increase a swing width of the differential amplification signal in response to a swing width increase signal. The control circuit may be configured to generate the swing width decrease signal and the swing width increase signal according to a swing width increase/decrease selection signal.

In an embodiment, a receiving circuit of a semiconductor apparatus may include a first amplification circuit, an equalization circuit, a swing width adjustment circuit and a control circuit. The first amplification circuit may be configured to amplify an input signal according to a reference voltage to generate a differential amplification signal, and to transmit the differential amplification signal to a first signal line and a second signal line. The equalization circuit may be coupled to the first signal line and the second signal line, and configured to decrease a swing width of the differential amplification signal in response to a swing width decrease signal, and to increase a swing width of the differential amplification signal in response to a swing width increase signal. The swing width adjustment circuit may be coupled between the equalization circuit and a ground, and configured to adjust an increase amount and a decrease amount of the swing width of the differential amplification signal according to a swing width adjustment code. The control circuit may be configured to generate the swing width decrease signal and the swing width increase signal according to a swing width increase/decrease selection signal.

### BRIEF DESCRIPTION OF THE DRAWINGS

FIG. 1 is a diagram illustrating a configuration of a receiving circuit according to an embodiment of the present disclosure.

FIG. 2 is a diagram illustrating a configuration of a first amplification circuit of FIG. 1 according to an embodiment of the present disclosure.

FIG. 3 is a diagram illustrating a configuration of an equalization circuit of FIG. 1 according to an embodiment of the present disclosure.

FIG. 4 is a diagram illustrating a configuration of a control circuit of FIG. 1 according to an embodiment of the present disclosure.

FIG. 5 is a diagram illustrating an equalization operation of a receiving circuit according to an embodiment of the present disclosure.

FIG. 6 is a diagram illustrating a configuration of a receiving circuit according to another embodiment of the present disclosure.

FIG. 7 is a diagram illustrating a configuration of a swing width adjustment circuit of FIG. 6 according to an embodiment of the present disclosure.

FIG. 8 is a diagram illustrating an equalization operation of a receiving circuit according to another embodiment of the present disclosure.

### DETAILED DESCRIPTION

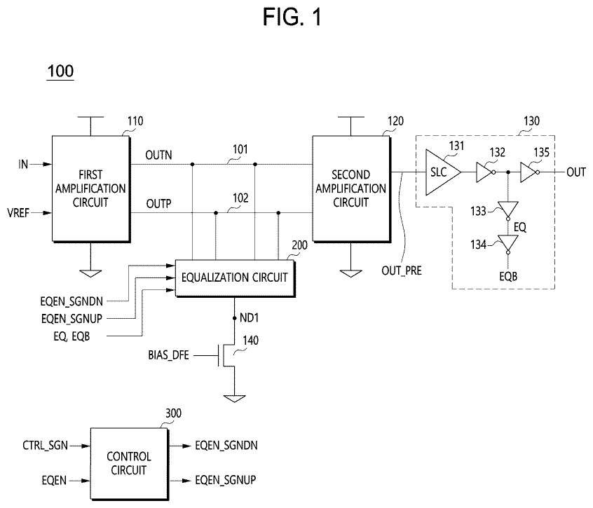

Hereinafter, embodiments of the present disclosure will be described in more detail with reference to the accompanying drawings. Various embodiments of the present disclosure can improve signal transmission efficiency by adjusting the swing width of the signal. FIG. 1 is a diagram illustrating a configuration of a receiving circuit 100 according to an embodiment. Referring to FIG. 1, the receiving circuit 100 according to an embodiment may include a first amplification circuit 110, a second amplification circuit 120, an equalization control signal generation circuit 130, a current sink circuit 140, an equalization circuit 200, and a control circuit 300.

The first amplification circuit 110 may amplify an input signal IN according to a reference voltage VREF to generate a first differential amplification signal OUTN/OUTP, and transmit the first differential amplification signal OUTN/OUTP to a first signal line 101 and a second signal line 102. The first amplification circuit 110 may transmit one of the first differential amplification signals OUTN/OUTP, for example, a first amplification signal OUTN to the first signal line 101, and a second amplification signal OUTP to the second signal line 102.

The second amplification circuit 120 may amplify the first differential amplification signal OUTN/OUTP to generate a preliminary output signal OUT_PRE. The second amplification circuit 120 may have the same circuit configuration as the first amplification circuit 110.

The equalization control signal generation circuit 130 may be input the preliminary output signal OUT_PRE and may output an output signal OUT and a first equalization control signal EQ and a second equalization control signal EQB. The equalization control signal generation circuit 130 may generate the output signal OUT and the first equalization control signal EQ and the second equalization control signal EQB according to the preliminary output signal OUT_PRE.

The equalization control signal generation circuit 130 may include a slicer SLC 131 and a plurality of logic gates 132-135. The slicer 131 may remove noise components of the preliminary output signal OUT_PRE and may output a noise removed signal. The first logic gate 132 may output by inverting the signal output from the slicer 131. A second logic gate 133 may invert the output of the first logic gate 132 and output it as a first equalization control signal EQ. The third logic gate 134 may invert the first equalization control signal EQ and output it as a second equalization control signal EQB. The fourth logic gate 135 may invert the output of the first logic gate 132 to generate an output signal OUT.

Input signals IN may be input sequentially, for example, data may be input at 1-unit interval (hereinafter referred to as UI). A preliminary output signal OUT_PRE is passed through the slicer 131, the first logic gate 132, and the second logic gate 133 to generate a first equalization control signal EQ and a second equalization control signal EQB. Each of the first equalization control signal EQ and the second equalization control signal EQB may have a signal processing delay time corresponding to the second amplification circuit 120, the slicer 131, the first logic gate 132, the second logic gate 133, and the third logic gate 134. The signal processing delay time may be less than 1 UI. The equalization circuit 200 may perform an equalization operation on the current input signal IN according to the first equalization control signal EQ and the second equalization control signal EQB.

The equalization circuit 200 is coupled to the first signal line 101 and the second signal line 102, and can receive a swing width decrease signal EQEN_SGNDN, a swing width increase signal EQEN_SGNUP, a first equalization control signal EQ, and a second equalization control signal EQB.

The equalization circuit 200 may adjust a voltage level of the first signal line 101 according to the second equalization control signal EQB when the swing width decrease signal EQEN_SGNDN is activated, and adjust a voltage level of the second signal line 102 according to the first equalization control signal EQ to reduce the swing width of the first differential amplification signal OUTN/OUTP transmitted through the first signal line 101 and the second signal line 102.

When the swing width increase signal EQEN_SGNUP is activated, the equalization circuit 200 may adjust a voltage level of the second signal line 102 according to the second equalization control signal EQB and adjust a voltage level of the first signal line 101 according to the first equalization control signal EQ to increase the swing width of the first differential amplification signal OUTN/OUTP.

The current sink circuit 140 may be coupled to the equalization circuit 200 through the first node ND1. The current sink circuit 140 can adjust the amount of sink current in the equalization circuit 200 based on a bias voltage BIAS_DFE. The current sink circuit 140 may include a transistor.

The control circuit 300 may receive the swing width increase/decrease selection signal CTRL_SGN and the equalization enable signal EQEN as inputs and output the swing width decrease signal EQEN_SGNDN and the swing width increase signal EQEN_SGNUP. The control circuit 300 may selectively activate the swing width decrease signal EQEN_SGNDN and the swing width increase signal EQEN_SGNUP by combining the swing width increase/decrease selection signal CTRL_SGN and the equalization enable signal EQEN.

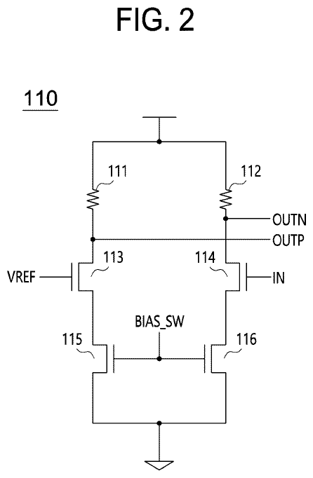

FIG. 2 is a diagram illustrating a configuration of the first amplification circuit 110 of FIG. 1. Referring to FIG. 2, the first amplification circuit 110 may include a plurality of resistors 111, 112 and a plurality of transistors 113-116.

The second resistor 112 may be coupled to a power supply. A voltage by the second resistor 112 may be output as a first amplified signal OUTN of the first differential amplified signal OUTN/OUTP. The first resistor 111 may be coupled to the power supply in parallel with the second resistor 112. A voltage by the first resistor 111 may be output as a second amplified signal OUTP of the first differential amplified signal OUTN/OUTP. The first transistor 113 may have a drain coupled to the other end of the first resistor 111 and may receive a reference voltage VREF input to its gate. A second transistor 114 may have a drain coupled to the other end of a second resistor 112 and may receive an input signal IN at its gate. The third transistor 115 may have a drain coupled to a source of the first transistor 113, a gate with a bias voltage BIAS_SW input, and a source coupled to a ground. The fourth transistor 116 has a drain coupled to the source of the second transistor 114, a gate with a bias voltage BIAS_SW input, and a source coupled to the ground. The bias voltage BIAS_SW may be supplied or blocked by external control.

The first amplification circuit 110 can generate the first differential amplification signal OUTN/OUTP by pulling down the first amplification signal OUTN when the level of the input signal IN is high relative to the reference voltage VREF and pulling down the second amplification signal OUTP when the level of the input signal IN is low relative to the reference voltage VREF.

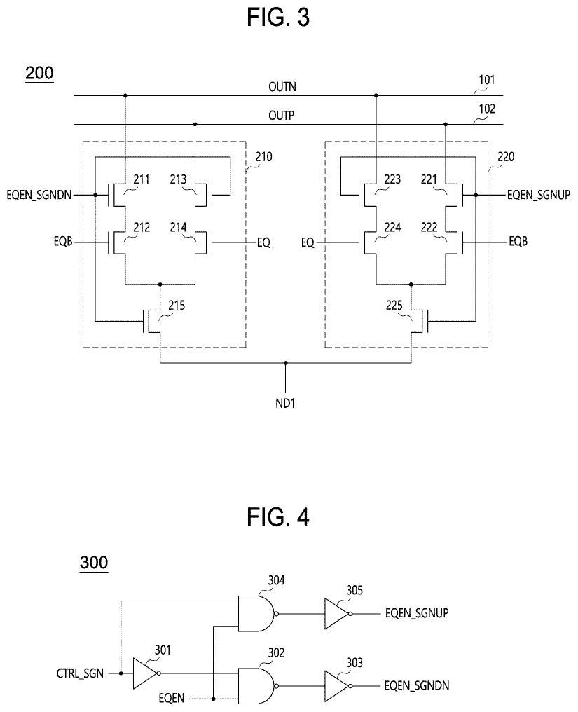

FIG. 3 is a diagram illustrating a configuration of the equalization circuit 200 of FIG. 1. Referring to FIG. 3, the equalization circuit 200 may include a first equalization circuit 210 and a second equalization circuit 220.

The first equalization circuit 210 may, when the swing width decrease signal EQEN_SGNDN is activated, adjust the voltage level of the first signal line 101 according to the second equalization control signal EQB and adjust the voltage level of the second signal line 102 according to the first equalization control signal EQ to reduce the swing width of the first differential amplification signal OUTN/OUTP transmitted through the first signal line 101 and the second signal line 102.

The first equalization circuit 210 may include a plurality of switching elements 211-215. Each of the plurality of switching elements 211-215 may comprise a transistor. The first switching element, i.e., the first transistor 211, may have a drain coupled to the first signal line 101 and to a gate with a swing width decrease signal EQEN_SGNDN input. The second switching element, that is, the second transistor 212, has a drain coupled to the source of the first transistor 211 and may receive a second equalization control signal EQB at its gate. The third switching element, namely the third transistor 213, has a drain coupled to the second signal line 102, and a swing width decrease signal EQEN_SGNDN may be input to a gate. The fourth switching element, that is, the fourth transistor 214, has a drain coupled to the source of the third transistor 213 and may receive a first equalization control signal EQ at its gate. The fifth switching element, i.e., the fifth transistor 215, has a drain coupled in common with the source of the second transistor 212 and the source of the fourth transistor 214, a gate with a swing width decrease signal EQEN_SGNDN input, and a source coupled with the first node ND1.

When the swing width increase signal EQEN_SGNUP is activated, the second equalization circuit 220 may adjust a voltage level of the second signal line 102 according to the second equalization control signal EQB and adjust a voltage level of the first signal line 101 according to the first equalization control signal EQ to increase the swing width of the first differential amplification signal OUTN/OUTP.

The second equalization circuit 220 may include a plurality of switching elements 221-225. Each of the plurality of switching elements 221-225 may comprise a transistor. The first switching element, i.e., the first transistor 221, may have a drain coupled to the second signal line 102, and a swing width increase signal EQEN_SGNUP may be input to the gate. The second switching element, i.e., the second transistor 222, has a drain coupled to the source of the first transistor 221 and may receive a second equalization control signal EQB at its gate. The third switching element, namely the third transistor 223, has a drain coupled to the first signal line 101, and a swing width increase signal EQEN_SGNUP may be input to the gate. The fourth switching element, that is, the fourth transistor 224, has a drain coupled to the source of the third transistor 223 and may receive a first equalization control signal EQ at its gate. The fifth switching element, i.e., the fifth transistor 225, has a drain coupled in common with the source of the second transistor 222 and the source of the fourth transistor 224, a gate receiving a swing width increase signal EQEN_SGNUP, and a source coupled with the first node ND1.

FIG. 4 is a diagram illustrating a configuration of the control circuit 300 of FIG. 1. Referring to FIG. 4, the control circuit 300 may include a plurality of logic gates 301-305.

A first logic gate 301 may invert and output a swing width increase/decrease selection signal CTRL_SGN. The second logic gate 302 may output the output of the first logic gate 301 and the equalization enable signal EQEN by a NAND operation. The third logic gate 303 may invert the output of the second logic gate 302 and output it as a swing width decrease signal EQEN_SGNDN. The fourth logic gate 304 may output of the swing width increase/decrease selection signal CTRL_SGN and the equalization enable signal EQEN by a NAND operation. The fifth logic gate 305 may invert the output of the fourth logic gate 304 and output it as a swing width increase signal EQEN_SGNUP.

The control circuit 300 may deactivate the swing width decrease signal EQEN_SGNDN and the swing width increase signal EQEN_SGNUP to a low level independent of the swing width increase/decrease selection signal CTRL_SGN when the equalization enable signal EQEN is deactivated to a low level, that is, when the equalization function is deactivated.

When the equalization enable signal EQEN is enabled to a high level, that is, when the equalization function is enabled, the control circuit 300 may select whether to increase or decrease the swing width in performing the equalization function depending on the level of the swing width increase/decrease selection signal CTRL_SGN. For example, when the swing width increase/decrease selection signal CTRL_SGN is at a low level, the swing width decrease signal EQEN_SGNDN is output at a high level and the swing width increase signal EQEN_SGNUP is output at a low level so that the equalization function of the swing width decrease method is selected. On the other hand, when the swing width increase/decrease selection signal CTRL_SGN is at a high level, the equalization function of the swing width increase method is selected by outputting the swing width decrease signal EQEN_SGNDN at a low level and the swing width increase signal EQEN_SGNUP at a high level.

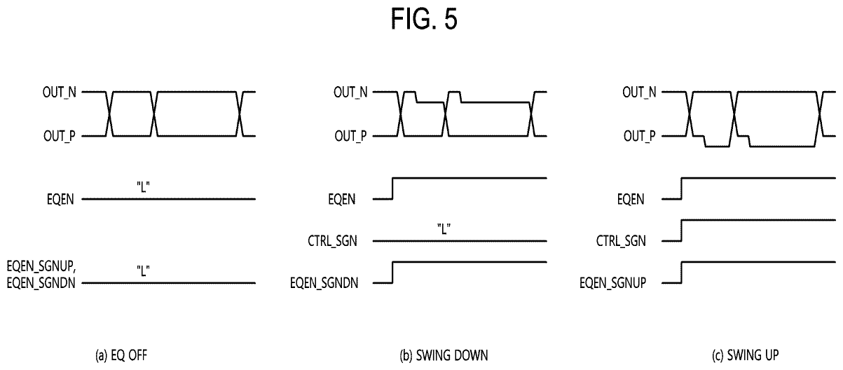

FIG. 5 is a diagram illustrating an equalization operation of the receiving circuit 100 according to an embodiment. The equalization operation of the receiving circuit 100 according to an embodiment will be described with reference to FIGS. 3 to 5.

First, when the equalization function is disabled (i.e., EQ OFF), as shown in (a) of FIG. 5, the equalization enable signal EQEN is at a low level (i.e., “L”), so the swing width decrease signal EQEN_SGNDN and the swing width increase signal EQEN_SGNUP are output at a low level.

Because the swing width decrease signal EQEN_SGNDN and the swing width increase signal EQEN_SGNUP are low-level, both the first equalization circuit 210 and the second equalization circuit 220 are disabled so that the swing width of the first differential amplification signal OUTN/OUTP is maintained at the level output from the first amplification circuit 110 and the output signal OUT can be output accordingly.

When the equalization function of the swing width decrease method is selected (i.e., SWING DOWN), as shown in (b) of FIG. 5, the equalization enable signal EQEN is high level and the swing width increase/decrease selection signal CTRL_SGN is at a low level, so the swing width decrease signal EQEN_SGNDN is output at a high level and the swing width increase signal EQEN_SGNUP is output at a low level.

Because the swing width decrease signal EQEN_SGNDN is high level and the swing width increase signal EQEN_SGNUP is low level, the first equalization circuit 210 is enabled and the second equalization circuit 220 is disabled.

The first equalization circuit 210 may drop the voltage level of the second signal line 102 according to the first equalization control signal EQ to reduce the swing width of the first differential amplification signal OUTN/OUTP.

When the equalization function of the swing width increase method is selected (i.e., SWING UP), as shown in (c) of FIG. 5, the equalization enable signal EQEN is high level and the swing width increase/decrease selection signal CTRL_SGN is high level, so the swing width decrease signal EQEN_SGNDN is output to a low level and the swing width increase signal EQEN_SGNUP is output to a high level.

Because the swing width decrease signal EQEN_SGNDN is low level and the swing width increase signal EQEN_SGNUP is high level, the first equalization circuit 210 is disabled and the second equalization circuit 220 is enabled.

The second equalization circuit 220 may drop the voltage level of the first signal line 101 according to the first equalization control signal EQ to increase the swing width of the first differential amplification signal OUTN/OUTP.

The magnitude of the increase and decrease of the swing width may be determined by the current sink circuit 140. On the other hand, the swing width decrease method and the swing width increase method may be selected by a series of training operations. That is, the input signal IN may have different characteristics, such as signal integrity characteristics, that are the basis of signal quality depending on the environment of the transmitted channel. Therefore, the level of the swing width increase/decrease selection signal CTRL_SGN can be selected accordingly by selecting one of the swing width decrease method and the swing width increase method so that, in an embodiment, the quality of the output signal OUT is improved through the training operation. For example, when the swing width of the output signal OUT is large compared to the target level, the swing width increase/decrease selection signal CTRL_SGN can be set to a low level so that the equalization circuit 200 performs the equalization operation of the swing width decrease method. On the other hand, if the swing width of the output signal OUT is small compared to the target level, the swing width increase/decrease selection signal CTRL_SGN can be set to a high level so that the equalization circuit 200 performs an equalization operation in the swing width increase method.

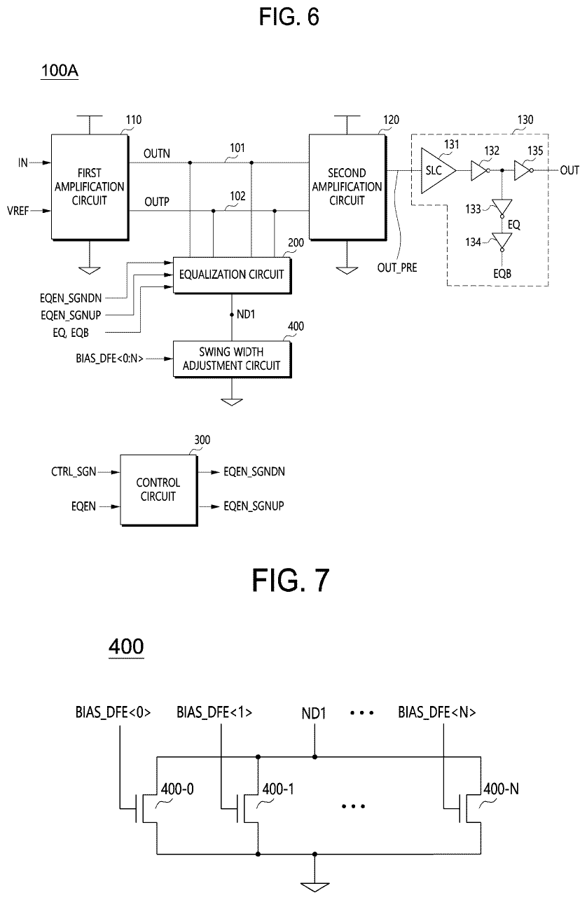

FIG. 6 is a diagram illustrating a configuration of the receiving circuit 100A according to another embodiment. Referring to FIG. 6, the receiving circuit 100A according to another embodiment of may include a first amplification circuit 110, a second amplification circuit 120, an equalization control signal generation circuit 130, an equalization circuit 200, a control circuit 300, and a swing width adjustment circuit 400.

The first amplification circuit 110 may amplify an input signal IN according to a reference voltage VREF to generate a first differential amplification signal OUTN/OUTP, and transmit the first differential amplification signal OUTN/OUTP to a first signal line 101 and a second signal line 102. The first amplification circuit 110 may transmit one of the first differential amplification signals OUTN/OUTP, for example, a first amplification signal OUTN to the first signal line 101, and a second amplification signal OUTP to the second signal line 102.

The second amplification circuit 120 may amplify the first differential amplification signal OUTN/OUTP to generate a preliminary output signal OUT_PRE.

The equalization control signal generation circuit 130 may generate an output signal OUT and a first equalization control signal EQ and a second equalization control signal EQB according to the preliminary output signal OUT_PRE.

The equalization control signal generation circuit 130 may include a slicer SLC 131 and a plurality of logic gates 132-135. The slicer 131 may remove noise components of the preliminary output signal OUT_PRE and may output a noise removed signal. The first logic gate 132 may output by inverting the signal output from the slicer 131. A second logic gate 133 may invert the output of the first logic gate 132 and output it as a first equalization control signal EQ. The third logic gate 134 may invert the first equalization control signal EQ and output it as a second equalization control signal EQB. The fourth logic gate 135 may invert the output of the first logic gate 132 to generate an output signal OUT.

Input signals IN may be input sequentially, for example, data may be input at 1-unit interval (UI). A preliminary output signal OUT_PRE is passed through the slicer 131, the first logic gate 132, and the second logic gate 133 to generate a first equalization control signal EQ and a second equalization control signal EQB. Each of the first equalization control signal EQ and the second equalization control signal EQB may have a signal processing delay time corresponding to the second amplification circuit 120, the slicer 131, the first logic gate 132, the second logic gate 133, and the third logic gate 134. The signal processing delay time may be less than 1 UI. The equalization circuit 200 may perform an equalization operation on the current input signal IN according to the first equalization control signal EQ and the second equalization control signal EQB.

The equalization circuit 200 is coupled to the first signal line 101 and the second signal line 102, and can receive a swing width decrease signal EQEN_SGNDN, a swing width increase signal EQEN_SGNUP, a first equalization control signal EQ, and a second equalization control signal EQB.

The equalization circuit 200 may adjust a voltage level of the first signal line 101 according to the second equalization control signal EQB when the swing width decrease signal EQEN_SGNDN is activated, and adjust a voltage level of the second signal line 102 according to the first equalization control signal EQ to reduce the swing width of the first differential amplification signal OUTN/OUTP transmitted through the first signal line 101 and the second signal line 102.

When the swing width increase signal EQEN_SGNUP is activated, the equalization circuit 200 may adjust a voltage level of the second signal line 102 according to the second equalization control signal EQB and adjust a voltage level of the first signal line 101 according to the first equalization control signal EQ to increase the swing width of the first differential amplification signal OUTN/OUTP.

The control circuit 300 may receive the swing width increase/decrease selection signal CTRL_SGN and the equalization enable signal EQEN as inputs and output the swing width decrease signal EQEN_SGNDN and the swing width increase signal EQEN_SGNUP. The control circuit 300 may selectively activate the swing width decrease signal EQEN_SGNDN and the swing width increase signal EQEN_SGNUP by combining the swing width increase/decrease selection signal CTRL_SGN and the equalization enable signal EQEN.

The swing width adjustment circuit 400 is coupled between the equalization circuit 200 and the ground, and can adjust the amount of increase and decrease of the swing width of the first differential amplification signal OUTN/OUTP according to the swing width adjustment code BIAS_DFE<0:N>.

FIG. 7 is a diagram illustrating a configuration of the swing-width adjustment circuit 400 of FIG. 6. Referring to FIG. 7, the swing width adjustment circuit 400 may be configured to have a current driving capability in a binary weighted manner. Swing width adjustment circuit 400 may include a plurality of current sink circuits 400-0-400-N. In an embodiment, N may be a natural number greater than 1.

The plurality of current sink circuits 400-O-400-N may be coupled in parallel with the equalization circuit 200 through the first node ND1. The plurality of current sink circuits 400-O-400-N can activate the current path in response to each signal bit of the swing width adjustment code BIAS_DFE<0:N>.

The swing width adjustment circuit 400 may vary the amount of sink current in the equalization circuit 200 according to the value of the swing width adjustment code BIAS_DFE<0:N> so that the amount of increase and decrease in the swing width of the first differential amplification signal OUTN/OUTP is adjusted.

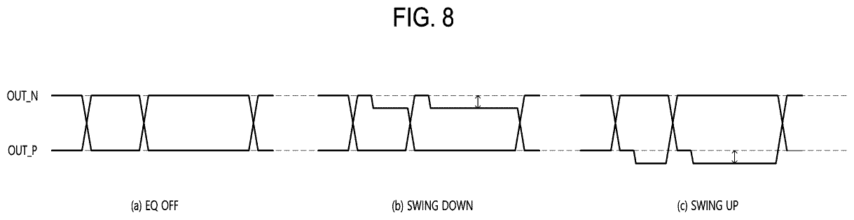

FIG. 8 is a diagram illustrating an equalization operation of the receiving circuit according to another embodiment. The equalization operation of the receiving circuit 100A according to another embodiment will be described with reference to FIGS. 6 to 8.

First, when the equalization function is disabled, as shown in (a) of FIG. 8, the equalization enable signal EQEN is at a low level, so the swing width decrease signal EQEN_SGNDN and the swing width increase signal EQEN_SGNUP are output at a low level.

Because the swing width decrease signal EQEN_SGNDN and the swing width increase signal EQEN_SGNUP are low-levels, both the first equalization circuit 210 and the second equalization circuit 220 are disabled so that the swing width of the first differential amplification signal OUTN/OUTP is maintained at the level output from the first amplification circuit 110 and the output signal OUT can be output accordingly.

When the equalization function of the swing width decrease method is selected, as shown in (b) of FIG. 8, the equalization enable signal EQEN is high level and the swing width increase/decrease selection signal CTRL_SGN is at a low level, so the swing width decrease signal EQEN_SGNDN is output at a high level and the swing width increase signal EQEN_SGNUP is output at a low level.

Because the swing width decrease signal EQEN_SGNDN is high level and the swing width increase signal EQEN_SGNUP is low level, the first equalization circuit 210 is enabled and the second equalization circuit 220 is disabled.

The first equalization circuit 210 may drop the voltage level of the second signal line 102 according to the first equalization control signal EQ to reduce the swing width of the first differential amplification signal OUTN/OUTP.

The swing width adjustment circuit 400 can adjust the amount of decrease in the swing width of the first differential amplification signal OUTN/OUTP by varying the amount of sink current of the equalization circuit 200 according to the value of the swing width adjustment code BIAS_DFE<0:N>.

When the equalization function of the swing width increase method is selected, as shown in (c) of FIG. 8, the equalization enable signal EQEN is high level and the swing width increase/decrease selection signal CTRL_SGN is high level, so the swing width decrease signal EQEN_SGNDN is output to a low level and the swing width increase signal EQEN_SGNUP is output to a high level.

Because the swing width decrease signal EQEN_SGNDN is low level and the swing width increase signal EQEN_SGNUP is high level, the first equalization circuit 210 is disabled and the second equalization circuit 220 is enabled.

The second equalization circuit 220 may drop the voltage level of the first signal line 101 according to the first equalization control signal EQ to increase the swing width of the first differential amplification signal OUTN/OUTP.

The swing width adjustment circuit 400 can adjust the amount of decrease in the swing width of the first differential amplification signal OUTN/OUTP by varying the amount of sink current of the equalization circuit 200 according to the value of the swing width adjustment code BIAS_DFE<0:N>.

On the other hand, the swing width decrease method and the swing width increase method may be selected by a series of training operations. That is, the input signal IN may have different characteristics, such as signal integrity characteristics, that are the basis of signal quality depending on the environment of the transmitted channel. Therefore, the level of the swing width increase/decrease selection signal CTRL_SGN and the value of the swing width adjustment code BIAS_DFE<0:N> can be selected accordingly by selecting one of the swing width decrease method and the swing width increase method so that, in an embodiment, the quality of the output signal OUT is improved through the training operation. For example, if the swing width of the output signal OUT is large compared to the target level, the swing width increase/decrease selection signal CTRL_SGN can be set to a low level so that the equalization circuit 200 selects the equalization operation of the swing width decrease method and adjusts the value of the swing width adjustment code BIAS_DFE<0:N> so that the swing width of the output signal OUT approaches the target level. On the other hand, if the swing width of the output signal OUT is smaller than the target level, the swing width increase/decrease selection signal CTRL_SGN can be set to a high level so that the equalization circuit 200 selects the equalization operation of the swing width increase method and adjusts the value of the swing width adjustment code BIAS_DFE<0:N> so that the swing width of the output signal OUT approaches the target level.

While certain embodiments have been described above, it will be understood to those skilled in the art that the embodiments described are by way of example only. Accordingly, the equalization circuit and the receiving circuit including the same should not be limited based on the described embodiments. Rather, the equalization circuit and the receiving circuit including the same described herein should only be limited in light of the claims that follow when taken in conjunction with the above description and accompanying drawings.

What is claimed is:

1. An equalization circuit comprising:
a first equalization circuit configured, when a swing width decrease signal is activated, to adjust a voltage level of a first signal line in accordance with a second equalization control signal and to adjust a voltage level of a second signal line in accordance with a first equalization control signal to decrease a swing width of a differential amplification signal transmitted over the first signal line and the second signal line, and
a second equalization circuit configured to, when a swing width increase signal is activated, to adjust the voltage level of the second signal line in accordance with the second equalization control signal and to adjust the voltage level of the first signal line in accordance with the first equalization control signal to increase a swing width of the differential amplification signal.

2. The equalization circuit of claim 1, the first equalization circuit includes:
a first switching element coupled to the first signal line and operating in accordance with the swing width decrease signal,
a second switching element coupled to the first switching element and operating in accordance with the second equalization control signal,
a third switching element coupled to the second signal line and operating in accordance with the swing width decrease signal, and
a fourth switching element coupled with the third switching element and operating in accordance with the first equalization control signal.

3. The equalization circuit of claim 1, the second equalization circuit includes:
a first switching element coupled to the second signal line and operating in accordance with the swing width increase signal,
a second switching element coupled to the first switching element and operating in accordance with the second equalization control signal,
a third switching element coupled to the first signal line and operating in accordance with the swing width increase signal, and
a fourth switching element coupled with the third switching element and operating in accordance with the first equalization control signal.

4. The equalization circuit of claim 1, further comprising a control circuit configured to selectively activate the swing width decrease signal and the swing width increase signal using a combination of an equalization enable signal and a swing width increase/decrease (increase and decrease) selection signal.

5. A receiving circuit of a semiconductor apparatus comprising:
a first amplification circuit configured to amplify an input signal according to a reference voltage to generate a differential amplification signal, and to transmit the differential amplification signal to a first signal line and a second signal line;
an equalization circuit coupled to the first signal line and the second signal line, and configured to decrease a swing width of the differential amplification signal in response to a swing width decrease signal, and to increase a swing width of the differential amplification signal in response to a swing width increase signal; and
a control circuit configured to generate the swing width decrease signal and the swing width increase signal according to a swing width increase/decrease (increase and decrease) selection signal.

6. The receiving circuit of claim 5, wherein the equalization circuit includes:
a first equalization circuit configured, when the swing width decrease signal is activated, to adjust a voltage level of the first signal line in accordance with a second equalization control signal and to adjust a voltage level of the second signal line in accordance with a first equalization control signal to decrease the swing width of the differential amplification signal transmitted over the first signal line and the second signal line, and
a second equalization circuit configured to, when the swing width increase signal is activated, to adjust the voltage level of the second signal line in accordance with the second equalization control signal and to adjust the voltage level of the first signal line in accordance with the first equalization control signal to increase the swing width of the differential amplification signal.

7. The receiving circuit of claim 6, the first equalization circuit includes:
a first switching element coupled to the first signal line and operating in accordance with the swing width decrease signal,
a second switching element coupled to the first switching element and operating in accordance with the second equalization control signal,
a third switching element coupled to the second signal line and operating in accordance with the swing width decrease signal, and
a fourth switching element coupled with the third switching element and operating in accordance with the first equalization control signal.

8. The receiving circuit of claim 6, the second equalization circuit includes:
a first switching element coupled to the second signal line and operating in accordance with the swing width increase signal,
a second switching element coupled to the first switching element and operating in accordance with the second equalization control signal,
a third switching element coupled to the first signal line and operating in accordance with the swing width increase signal, and
a fourth switching element coupled with the third switching element and operating in accordance with the first equalization control signal.

9. The receiving circuit of claim 5, wherein the control circuit is configured to selectively activate the swing width decrease signal and the swing width increase signal using a combination of an equalization enable signal and a swing width increase/decrease selection signal.

10. The receiving circuit of claim 6, further comprising:
a second amplification circuit configured to amplify the differential amplification signal to generate a preliminary output signal; and
an equalization control signal generation circuit configured to generate the first equalization control signal and the second equalization control signal according to the preliminary output signal.

11. A receiving circuit of a semiconductor apparatus comprising:
a first amplification circuit configured to amplify an input signal according to a reference voltage to generate a differential amplification signal, and to transmit the differential amplification signal to a first signal line and a second signal line;
an equalization circuit coupled to the first signal line and the second signal line, and configured to decrease a swing width of the differential amplification signal in response to a swing width decrease signal, and to increase a swing width of the differential amplification signal in response to a swing width increase signal;
a swing width adjustment circuit coupled between the equalization circuit and a ground, and configured to adjust an increase amount and a decrease amount of the swing width of the differential amplification signal according to a swing width adjustment code; and
a control circuit configured to generate the swing width decrease signal and the swing width increase signal according to a swing width increase/decrease (increase and decrease) selection signal.

12. The receiving circuit of claim 11, wherein the equalization circuit includes:
a first equalization circuit configured, when the swing width decrease signal is activated, to adjust a voltage level of the first signal line in accordance with a second equalization control signal and to adjust a voltage level of the second signal line in accordance with a first equalization control signal to decrease the swing width of the differential amplification signal transmitted over the first signal line and the second signal line, and
a second equalization circuit configured to, when the swing width increase signal is activated, to adjust the voltage level of the second signal line in accordance with the second equalization control signal and to adjust the voltage level of the first signal line in accordance with the first equalization control signal to increase the swing width of the differential amplification signal.

13. The receiving circuit of claim 12, the first equalization circuit includes:
a first switching element coupled to the first signal line and operating in accordance with the swing width decrease signal,
a second switching element coupled to the first switching element and operating in accordance with the second equalization control signal,
a third switching element coupled to the second signal line and operating in accordance with the swing width decrease signal, and
a fourth switching element coupled with the third switching element and operating in accordance with the first equalization control signal.

14. The receiving circuit of claim 12, the second equalization circuit includes:
a first switching element coupled to the second signal line and operating in accordance with the swing width increase signal,
a second switching element coupled to the first switching element and operating in accordance with the second equalization control signal,
a third switching element coupled to the first signal line and operating in accordance with the swing width increase signal, and
a fourth switching element coupled with the third switching element and operating in accordance with the first equalization control signal.

15. The receiving circuit of claim 11, wherein the swing width adjustment circuit comprises a plurality of current sink circuits coupled in parallel with the equalization circuit and operating in response to each signal bit of the swing width adjustment code.

16. The receiving circuit of claim 11, wherein the control circuit is configured to selectively activate the swing width decrease signal and the swing width increase signal using a combination of an equalization enable signal and a swing width increase/decrease selection signal.

17. The receiving circuit of claim 12, further comprising:
a second amplification circuit configured to amplify the differential amplification signal to generate a preliminary output signal; and
an equalization control signal generation circuit configured to generate the first equalization control signal and the second equalization control signal according to the preliminary output signal.
